(19) United States
(12) Patent Application Publication
(10) Pub. No.: US 2002/0079882 A1
(43) Pub. Date: Jun. 27, 2002

(54) Autohandler and testing method

(75) Inventors: Tetsuya Okudaira, Inasa-gun (JP); Mamoru Hironaka, Hamamatsu-shi (JP)

Correspondence Address: OLIFF & BERRIDGE, PLC, P.O. BOX 19928, ALEXANDRIA, VA, 22320, US

(73) Assignee: ANDO ELECTRIC CO., LTD., Tokyo (JP)

(21) Appl. No.: 09/988,361

(22) Filed: Nov. 19, 2001

(30) Foreign Application Priority Data
Dec. 25, 2000 (JP) 2000-392773

(51) Int. Cl. G01R 1/00

(52) U.S. Cl. 324/158.1

(57) ABSTRACT

An autohandler for continuously processing devices for a shorter total processing time, for every device. The autohandler comprises: a loader (11) in which a tray (2) including devices which have not been tested is loaded; a sending shuttle (12) for transferring the tray to a test preparative position (P1); a test stage (20) for holding the tray on the sending shuttle waiting at the test preparative position, transferring the devices kept included in the tray to a test section in order, and transferring the tray to a receiving preparative position (P2); a receiving shuttle (13) for receiving the tray from the test stage at the receiving preparative position, and transferring the tray to a receiving buffer (P3); and a sorting section for sorting the devices in the tray on the receiving shuttle, on the basis of results of the test carried out by the test section.

### BACKGROUND OF THE INVENTION

1. Field of the Invention

The present invention relates to an autohandler and so on, for transferring devices which have not been tested to a test section, and sorting devices which have been tested on the basis of results of a test carried out by the test section.

2. Description of Related Art

A structure of an autohandler according to an earlier development will be explained with reference to FIG. 5.

An autohandler according to an earlier development comprises a loader 51, an empty tray buffer 52, an unloader 53, a sorting unit 54, a sending hand 55, a sending shuttle 56, a test hand 57, a receiving shuttle 58, and a receiving hand 59.

The loader 51 contains a plurality of trays 50 loaded thereon. Each tray 50 includes a plurality of ICs (devices) 1 which have not been tested yet, therein. The ICs 1 are removed from the tray 50 by the sending hand 55 in order. When all ICs 1 are removed from the tray 50 and the tray 50 becomes empty, the tray 50 is transferred to the empty tray buffer 52.

The empty tray buffer 52 temporarily contains the tray 50 which is empty, therein.

The unloader 53 contains a plurality of trays 50 therein. Each tray 50 includes a plurality of ICs 1 which have been tested to be decided a non-defective device, therein. When the unloader 53 receives the tray 50 which is empty, transferred from the empty tray buffer 52, the unloader 53 fills the tray 50 which is empty with the ICs 1 which have been tested to be decided a non-defective device.

The sorting unit 54 contains one tray 50 therein. The tray 50 includes ICs 1 which have been tested to be decided a defective device, therein.

The sending hand 55 adsorbs ICs 1 which have not been tested yet in the tray 50 loaded on the loader 51, one by one, and transfers the ICs 1 to on the sending shuttle 56 in order.

The sending shuttle 56 transfers the ICs 1 received from the sending hand 55, to an adsorption position S2 of the test hand 57, one by one.

The test hand 57 adsorbs the IC 1 on the sending the shuttle 56. Then, when the test hand 57 rotates 180 degrees according to a rotation of a rotational arm 60, the test hand 57 transfers the adsorbed IC 1 to a position opposite to an IC socket 4 (a test section). Then, when a predetermined time passes after the test hand 57 brings the IC 1 into pressure contact with the IC socket 4, that is, when the test section finishes an electric characteristic test of the IC 1, the test hand 57 separates the IC 1 from the IC socket 4. Thereafter, when the test hand 57 rotates 180 degrees according to the rotation of the rotational arm 60, the test hand 57 transfers the adsorbed IC 1 on the receiving shuttle 56.

The receiving shuttle 58 receives the IC 1 which has been tested from the test hand 57, and transfers the received IC 1 to an adsorption position S4 of the receiving hand 59, one by one.

The receiving hand 59 adsorbs the IC 1 on the receiving shuttle 58. Then, while the receiving hand 59 transfers the IC 1 decided to be a non-defective device to the unloader 53, the receiving hand 59 transfers the IC 1 decided to be a defective device to the sorting unit 54.

The IC socket 4 is arranged right under a turning orbit of the test hand 57, and electrically connected to an IC tester which is not shown in figures. Because a contactor is provided at the IC socket 4, the IC tester tests the electric characteristic of the IC 1 in a state wherein a lead of the IC is contacted with the contactor.

Next, a behavior and a processing time of each unit of the above-described autohandler will be explained with reference to FIG. 6.

A behavior of the sending hand 55 comprises a step of moving from on the sending shuttle 56 to the loader 51, a step of adsorbing the IC 1 of the loader 51, a step of moving from the loader 51 to on the sending shuttle 56, and a step of releasing an adsorption of the IC 1 on the sending shuttle 56. The sending hand 55 requires 3.8 seconds for carrying out a cycle of the above-described steps. That is, the sending hand 55 requires 3.8 seconds for transferring one IC 1 which has not been tested, of the loader 51 to on the sending shuttle 56.

A behavior of the sending shuttle 56 comprises a step of moving from an adsorption release position S1 of the sending hand 55 to the adsorption position S2 of the test hand 57, and a step of moving from the adsorption position S2 of the test hand 57 to the adsorption release position S1 of the sending hand 55. Herein, because when the sending shuttle 56 receives the IC 1 from the sending hand 55, and hands the IC 1 to the test hand 57, it is necessary that the sending shuttle 56 stops at the positions S1 and S2, the sending shuttle 56 requires 2.4 seconds for carrying out a cycle of the above-described steps. That is, the sending shuttle 56 requires 2.4 seconds for handing one IC 1 received from the sending hand 55 to the test hand 57.

A behavior of the test hand 57 comprises a step of adsorbing the IC 1 on the sending shuttle 56, a step of rotating from on the sending shuttle 56 to the position opposite to the IC socket 4, a step of bringing the adsorbed IC 1 into contact with the IC socket 4, a step of rotating from the position opposite to the IC socket 4 to on the receiving shuttle 58, a step of releasing the adsorption of the IC 1 on the receiving shuttle 58. The test hand 57 requires 3.0 seconds for carrying out a cycle of the above-described steps. That is, the test hand 57 requires 3.0 seconds for testing the electric characteristic of one IC 1. Herein, the test hand 57 comprises test hands 57-1 and 57-2 provided at both sides of the rotational arm 60, and the test hands 57-1 and 57-2 carry out the above-described cycle alternately. Therefore, waiting one of the test hands 57-1 and 57-2 carries out only the step of rotating with the working other.

A behavior of the receiving shuttle 58 comprises a step of moving from an adsorption release position S3 of the test hand 57 to the adsorption position S4 of the receiving hand 59, and a step of moving from the adsorption position S4 of the receiving hand 59 to the adsorption release position S3 of the test hand 57. Herein, because it is necessary that the receiving shuttle 58 stops at the positions S3 and S4 like the sending shuttle 56, the receiving shuttle 58 requires 2.4 seconds for carrying out a cycle of the above-described steps. That is, the receiving shuttle 58 requires 2.4 seconds for handing one IC 1 received from the test hand 57 to the holding hand 59.

A behavior of the receiving hand 59 comprises a step of adsorbing the IC 1 on the receiving shuttle 58, a step of moving from on the receiving shuttle 58 to the unloader 53 or the sorting unit 54, a step of releasing the adsorption of the IC 1 on the unloader 53 or the sorting unit 54, and a step of moving from the unloader 53 or the sorting unit 54 to on the receiving shuttle 58. The receiving hand 59 requires 3.8 seconds for carrying out a cycle of the above-described steps. That is, the receiving hand 59 requires 3.8 seconds for handing one IC 1 which has been tested from the receiving shuttle 58 to the unloader 53 or the sorting unit 54.

In the above-described autohandler according to an earlier development, the time requiring that the sending hand 55 or the receiving hand 59 carries out a cycle of the steps is longer than the time requiring that the test hand 57 carries out a cycle of the steps. Therefore, there has been a problem that it is impossible to shorten the total processing time for one IC, even if the test time for one IC, that is the contact time between the IC 1 and the IC socket 4, is shortened. That is, in case the test time for an IC 1 is short, the transfer processing of the IC 1 by the sending hand 55 or the receiving hand 59 becomes a bottleneck. Accordingly, because a waiting time occurs in the test processing of the IC 1 by the test hand 57, there has been a problem that the processing of the whole autohandler becomes inefficient.

### SUMMARY OF THE INVENTION

The present invention was developed in order to solve the problems as mentioned above.

An object of the present invention is to provide an autohandler and a testing method, for continuously processing devices for a shorter total processing time, for every device.

In accordance with a first aspect of the present invention, for example, as shown in FIGS. 1 and 2, an autohandler (100) for transferring devices (for example, ICs 1 and so on) which have not been tested to a test section (for example, an IC socket 4 and so on), and sorting devices which have been tested on the basis of results of a test carried out by the test section, comprises: a loader (11) in which a tray (2) including a plurality of devices which have not been tested is loaded; a sending shuttle (12) for transferring the tray loaded in the loader to a test preparative position (P1); a test stage (20) for holding the tray on the sending shuttle waiting at the test preparative position, transferring the devices which have not been tested and which are kept included in the tray held, to the test section in order, and transferring the tray to a receiving preparative position (P2) when the test section carries out the test to all the devices included in the tray; a receiving shuttle (13) for receiving the tray from the test stage at the receiving preparative position, and transferring the tray received to a receiving buffer (P3); and a sorting section (for example, an unloader 15, a sorting unit 16, and a receiving hand 14) for sorting the devices which have been tested in the tray on the receiving shuttle waiting in the receiving buffer, on the basis of results of the test carried out by the test section.

In accordance with a second aspect of the present invention, a testing method for handling and testing devices, comprises the steps of: loading a tray including a plurality of devices which have not been tested in a loader; transferring the tray loaded in the loader to a test preparative position; holding the tray waiting at the test preparative position; transferring the devices which have not been tested and which are kept included in the tray held, to a test section in order; testing the devices which are kept included in the tray by the test section; transferring the tray to a receiving preparative position when the test section tests all the devices included in the tray; receiving the tray at the receiving preparative position; transferring the tray received to a receiving buffer; and sorting the devices which have been tested in the tray waiting in the receiving buffer, on the basis of results tested by the test section.

According to the first aspect of the present invention, because the autohandler comprises a structure capable of transferring devices which have not been tested and which are kept included in the tray, to the test section in order, comparative with transferring devices which have not been tested to the test section one by one, it is possible to extremely shorten the processing time for every device when transferring every device which has not been tested to the test section. Consequently, in case the test time for every device is short, because the transfer time for every device can be shortened, it is possible to shorten the total processing time for every device.

Further, because each of the sending shuttle, the test stage and the receiving shuttle transfers devices kept included in the tray, it is possible to save an operation of exchanging the devices. Consequently, it is possible to reduce occurrences of an external defective, a static electricity breakdown and so on, of the device.

Preferably, in the autohandler according to the first aspect of the present invention, for example, as shown in FIG. 3, the tray (2) comprises a plurality of concave portions (2a) formed therein, at which the devices are provided respectively, and a plurality of connecting opening portions (2b) formed on bottom surfaces of the concave portions respectively, through which leads (3) of the devices provided at the concave portions go down the tray.

According to the autohandler as described above, because a plurality of concave portions are formed in the tray, and a plurality of connecting opening portions are formed on bottom surfaces of the concave portions, it is possible to transfer a plurality of devices at a time, and to test an electric characteristic of devices kept included in the tray.

Preferably, in the autohandler as described above, for example, as shown in FIG. 3, the test stage (20) comprises: a tray holding section (21) for holding the tray (2); a XY stage for moving the tray holding section horizontally, to arrange the devices included in the tray opposite the test section in order; and an elevator for moving the tray holding section vertically, to separate the devices included in the tray and arranged opposite the test section, from the test section.

According to the autohandler as described above, when the XY stage moves the tray holding section horizontally, devices included in the tray are arranged opposite the test section in order, and when the elevator moves the tray holding section vertically, the devices included in the tray and arranged opposite the test section are separated from the test section. Consequently, it is possible to transfer each device that is kept included in the tray to the test section.

Preferably, in the autohandler as described above, for example, for example, as shown in FIG. 3, the tray (2) comprises an engaged portion (for example, a guide hole 2e and so on) provided thereat, the tray holding section (21) comprises an engaging portion (for example, a guide pin 26 and so on) provided thereat, the engaging portion capable of engaging with and separating from the engaged portion, and the tray is positioned against the tray holding section, in a state wherein the engaging portion engages with the engaged portion.

According to the autohandler as described above, because the engaged portion is provided at the tray, and the engaging portion capable of engaging with and separating from the engaged portion is provided at the tray holding section, it is possible to exactly position the tray against the tray holding section. Consequently, it is possible to exactly transfer devices included in the tray to the test section.

Preferably, in the autohandler as described above, for example, as shown in FIG. 3, the tray holding section (21) comprises a base portion (22) provided thereat, having the engaging portion, and a contact pusher (25) provided at the base portion, for bringing each device included in the tray (2) into pressure contact with the tray.

Accordingly to the autohandler as described above, because the contact pusher brings each device included in the tray into pressure contact with the tray, it is possible to prevent each device from falling from the tray, and to exactly bring the lead of each device into contact with a contact portion such as a contactor or the like, provided at the test section.

Preferably, in autohandler as described above, for example, as shown in FIG. 3, the contact pusher (25) is prepared for every device included in the tray (2), and provided with play at the base portion (22).

According to the autohandler as described above, because the contact pusher is provided with play at the base portion, if there are uneven in positions at which devices are provided more or less, the contact pusher can absorb the unevenness. Consequently, it is possible that each contact pusher stably brings each device into pressure contact with the tray.

Preferably, in the autohandler as described above, for example, as shown in FIGS. 1 and 2, the sorting section comprises: an unloader (15) for receiving devices which have been tested to be decided to be a non-defective device; a sorting unit (16) for receiving devices which have been tested to be decided to be a defective device; a defective device transferring section (for example, a receiving hand 14 and so on) for selecting only devices decided to be a defective device from devices which have been tested in the tray on the receiving shuttle waiting in the receiving buffer, and transferring the devices selected to the sorting unit; and a non-defective device transferring section (for example, a receiving hand 14 and so on) for transferring the tray from which devices decided to be a defective device are removed and which includes only devices decided to be a non-defective device, from the receiving shuttle to the unloader.

According to the autohandler as described above, devices decided to be a defective device are removed from the tray and transferred to the sorting unit, and devices decided to be a non-defective device are kept included in the tray and transferred to the unloader. Consequently, it is possible to save an operation of exchanging the devices decided to be a non-defective device to the unloader.

Preferably, the autohandler as described above, further comprises a supplying section for supplying devices decided to be a non-defective device to portions in the tray, from which devices decided to be a defective device are removed and transferred to the sorting unit by the defective device transferring section and which become empty, to fill the tray with devices decided to be a non-defective device.

According to the autohandler as described above, because devices decided to be a non-defective device are supplied to portions in the tray, from which devices decided to be a defective device are removed and which become empty, it is possible to fill the tray of the unloader with devices to be a non-defective device.

### BRIEF DESCRIPTION OF THE DRAWINGS

The present invention will become more fully understood from the detailed description given hereinbelow and the accompanying drawings which are given by way of illustration only, and thus are not intended as a definition of the limits of the present invention, and wherein;

FIG. 1 is a plan view showing a schematic structure of an autohandler according to an embodiment of the present invention;

FIG. 2 is a front view showing the schematic structure of the autohandler shown in FIG. 1;

FIG. 3 is a section view showing for explaining a behavior of a test stage of the autohandler;

FIG. 4 is a time chart of each processing carried out in the autohandler shown in FIG. 1;

FIG. 5 is a plan view showing an exemplary schematic structure of an autohandler according to an earlier development; and

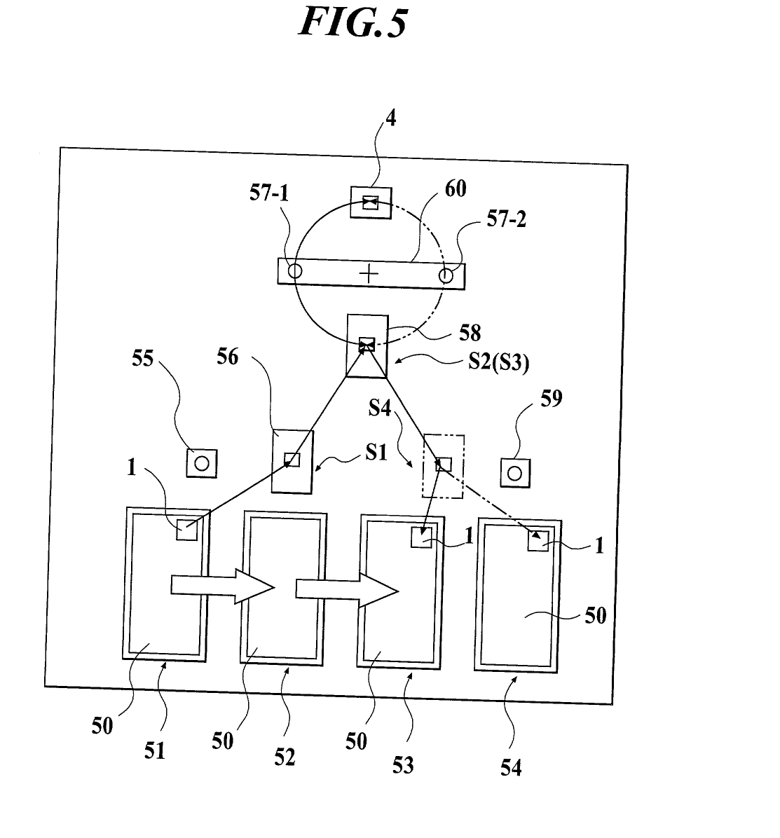

FIG. 6 is a time chart of each processing carried out in the autohandler shown in FIG. 5.

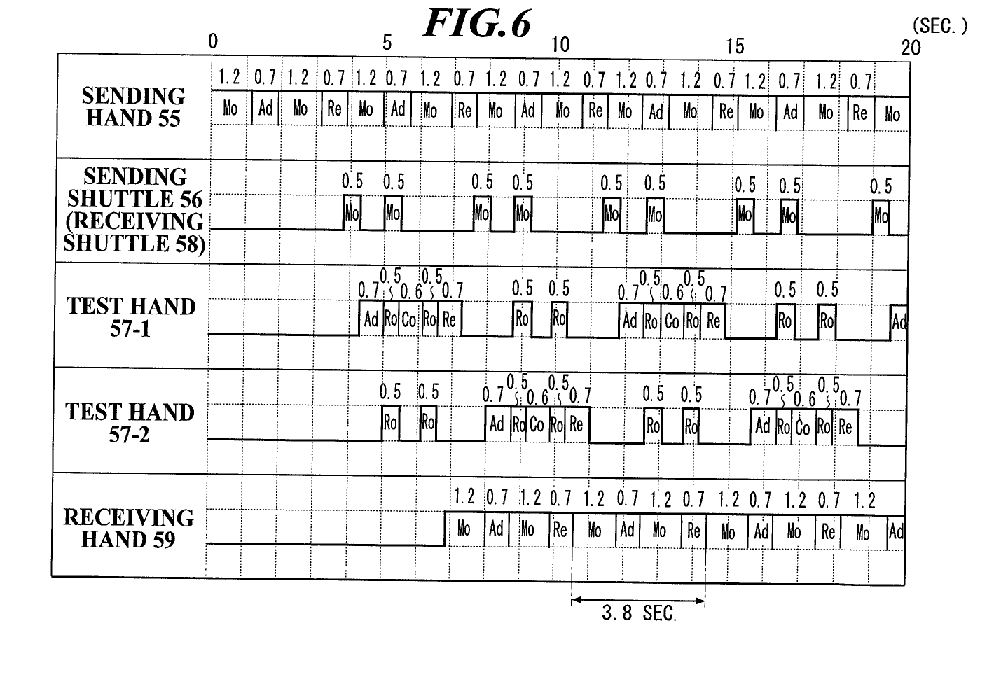

### PREFERRED EMBODIMENT OF THE INVENTION

Hereinafter, an embodiment of the present invention will be explained with reference to figures, in detail.

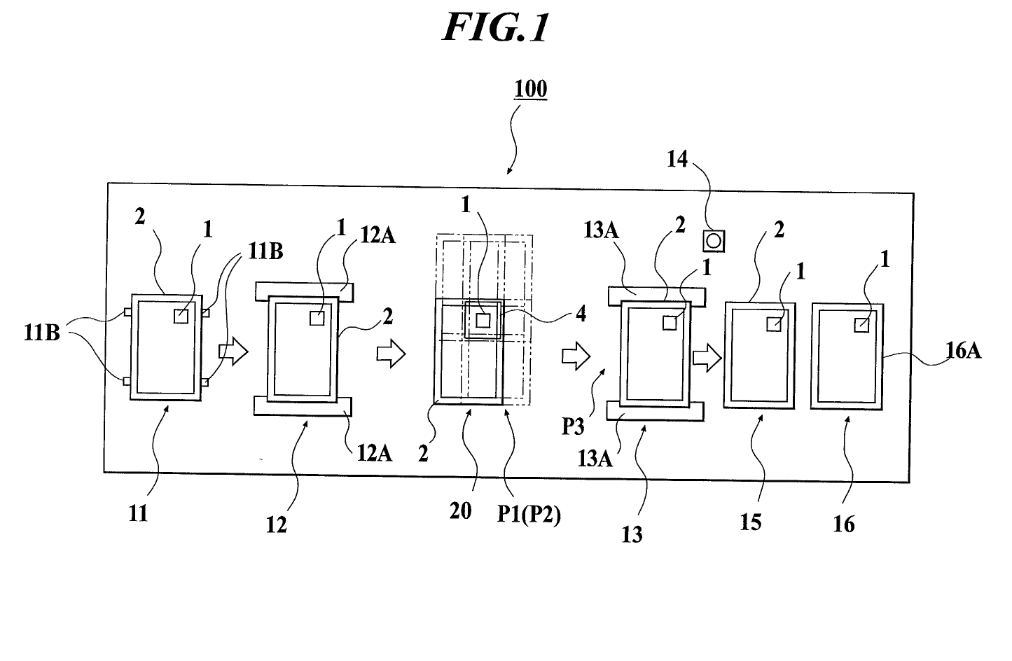

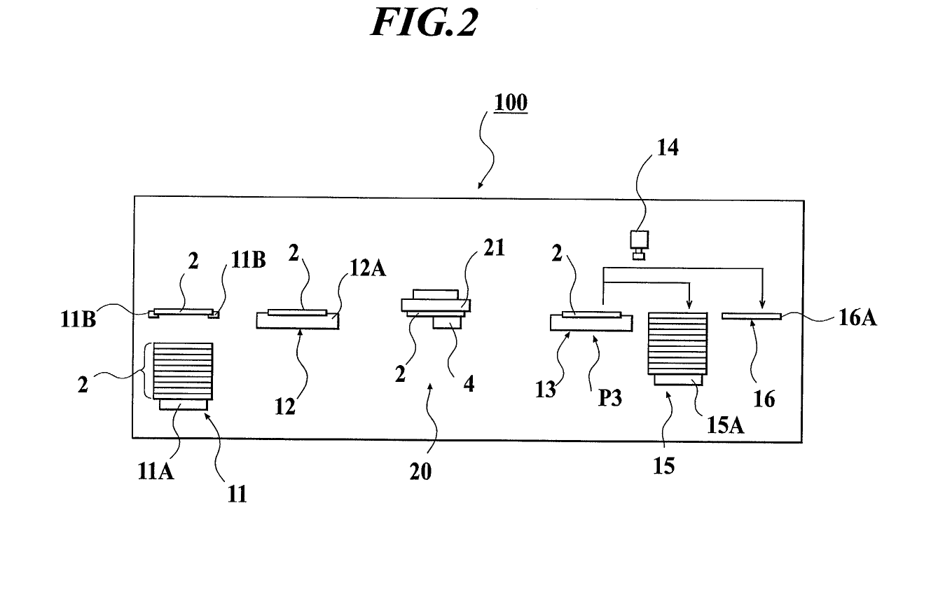

As shown in FIGS. 1 and 2, an autohandler 100 according to an embodiment of the present invention schematically comprises a loader 11, a sending shuttle 12, a test stage 20, a receiving shuttle 13, a receiving hand 14, an unloader 15 and a sorting unit 16.

The loader 11 comprises a tray loading table 11A held so as to go up and down and provided thereat. A plurality of trays 2 are stuck up and loaded on the tray loading table 11A, and each tray 2 includes a plurality of ICs (devices) 1 which have not been tested yet. Further, the loader 11 comprises a tray detection sensor which is not shown in figures, for detecting an upper end position of the trays 2 stuck up on the tray loading table 11A and a separating mechanism for separating the uppermost tray 2 from the trays 2 stuck up on the tray loading table 11A. For example, the separating mechanism consists of one pair of supporting arms 11B arranged opposite each other, a cylinder apparatus which is not shown in figures, for moving the supporting arms 11B horizontally in a direction of getting close to or separating from each other, and so on. For example, in order to separate the uppermost tray 2 from the trays 2 stuck up on the tray loading table 11A, first, the height of the tray loading table 11A is adjusted on the basis of a result of a detection carried out by the tray detection sensor such that the uppermost tray 2 is disposed at as high a position as the supporting arms 11B. Next, the cylinder apparatus is driven, and thereby the supporting arms 11B gets nearer to each other to hold the uppermost tray 2 therebetween. Then, the tray loading table 11A goes down, and thereby the uppermost tray 2 is separated from the other trays 2 on the tray loading table 11A.

The sending shuttle 12 comprises a tray loading table 12A on which the tray 2 is loaded, and moves between the loader 11 and the test stage 20. When the sending shuttle 12 receives the uppermost tray 2 separated by the separating mechanism of the loader 11, the sending shuttle 12 transfers the received tray 2 to a test preparative position P1 under the test stage 20. Then, the sending shuttle 12 hands the tray 2 on the tray loading table 12A to the test stage 20 at the test preparative position P1. After handing the tray 2, the sending shuttle 12 moves back to the loader 11 to receive the next tray 2.

The test stage 20 holds the tray 2 on the sending shuttle 12 waiting at the test preparative position P1, and transfers ICs 1 which have not been tested yet and which are kept included in the tray 2 held, to the IC socket 4 (test section) in order. Then, when the IC socket 4 finishes testing all the ICs 1 included in the tray 2, the test stage 20 transfers the tray 2 to a receiving preparative position P2.

The receiving shuttle 13 comprises a tray loading table 13A on which the tray 2 is loaded, and moves between the receiving preparative position P2 and the receiving butter P3. When the receiving shuttle 13 receives the tray 2 from the test stage 20 at the receiving preparative position P2, the receiving shuttle 13 transfers the received tray 2 to the receiving buffer P3. Then, the receiving shuttle 13 hands the tray 2 on the tray loading table 13A at the receiving buffer P3. After handing the tray 2, the receiving shuttle 13 moves back to the receiving preparative position P2 to receive the next tray 2.

The receiving hand 14 functions as a defective device transferring section of the present invention. Therefore, the receiving hand 14 selects only the ICs 1 decided to be a defective device from the ICs 1 which have been tested in the tray 2 on the receiving shuttle 13 waiting in the receiving buffer P3, and transfers the selected ICs 1 to the sorting unit 16. Further, the receiving hand 14 functions as a non-defective device transferring section of the present invention. Therefore, the receiving hand 14 transfers the tray 2 from which the ICs 1 decided to be a defective device are removed and which includes only the ICs 1 decided to be a non-defective device, from the receiving shuttle 13 to the unloader 15.

The unloader 15 comprises a tray loading table 15A held so as to go up and down and provided thereat. The unloader 15 receives the tray 2 including only the ICs 1 decided to be a non-defective device, from the receiving hand 14. Then, the unloader 15 stacks the received trays 2 on the tray loading table 15A.

The sorting unit 16 comprises a defective device receiving tray 16A including only the ICs 1 decided to be a defective device. That is, the sorting unit 16, the unloader 15 and the receiving hand 14 function as a sorting section of the present invention.

Next, the structure of the test stage 20 will be explained in detail.

The test stage 20 schematically comprises a tray holding unit 21 for holding the tray 2, an elevator not shown in figures, for moving the tray holding unit 21 vertically, and a XY stage not shown in figures, for moving the tray holding unit 21 horizontally.

The elevator moves the tray holding unit 21 vertically, and thereby brings the IC 1 included in the tray 2 arranged opposite the IC socket 4 into contact with and separate from the IC socket 4. The elevator may comprise a known structure. For example, the elevator may comprise a supporting unit for supporting the tray holding unit 21 so as to vertically move up and down, a motor as a drive power, a power transmitting mechanism (for example, a rack pinion mechanism, or a ball screw mechanism) for converting a rotational motion of the motor around an output shaft thereof to a lifting motion of the tray holding unit 21, and so on.

The XY stage moves the tray holding unit 21 horizontally, and thereby arranges the ICs 1 included in the tray 2, opposite the IC socket 4, in order. The XY stage may comprise a known structure. For example, the XY stage may comprise a X-coordinate slide table for holding the supporting unit supporting the tray holding unit 21 so as to move in the X-coordinate direction (one of directions on the horizontal plane), a Y-coordinate slide table for holding the X-coordinate slide table so as to move in the Y-coordinate direction (a direction perpendicular to the X-coordinate on the horizontal plane), a X-coordinate motor as a drive motor, a Y-coordinate motor as a drive motor, a X-coordinate power transmitting mechanism for converting a rotational motion of the X-coordinate motor around an output shaft thereof to a rectilinear motion of the supporting unit in the X-coordinate direction, a Y-coordinate power transmitting mechanism for converting a rotational motion of the Y-coordinate motor around an output shaft thereof to a rectilinear motion of the X-coordinate slide table in the Y-coordinate direction, and so on.

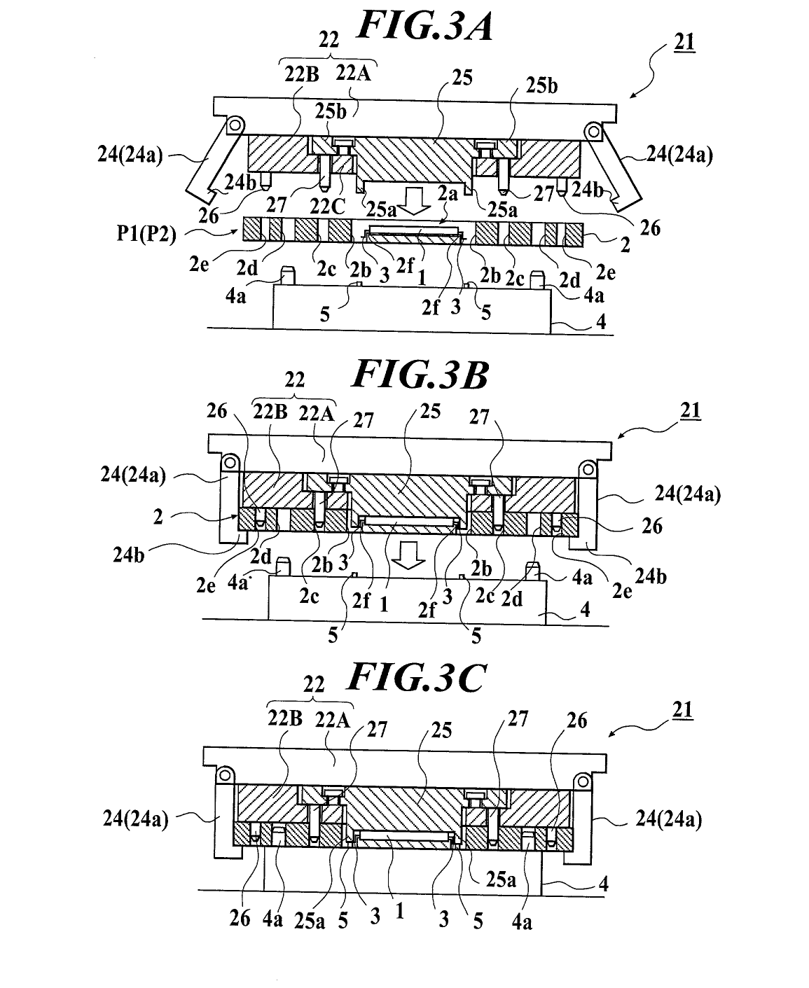

As shown in FIG. 3, the tray holding unit 21 schematically comprises a base unit 22, a contact pusher 25, an opening and closing clamp 24, and guide pins 26 and 27.

The base unit 22 comprises a board 22A and a pusher base 22B installed on a lower surface of the board 22A. The base unit 22 is held so as to move horizontally by the elevator and so as to move vertically by the XY stage.

The opening and closing clamp 24 comprises a pair of supporting arms 24a. Each of supporting arms 24a is installed at each side end portion of the board 22A so as to swing. Cylinder apparatuses not shown in figures are installed at the supporting arms 24a respectively, and when the cylinder apparatuses are driven, the supporting arms 24a can reversibly change between the state shown in FIG. 3A and the state shown in FIG. 3B. Further, the opening and closing clamp 24 comprises engaging portions 24b projecting into an inside and provided at top end portions of the supporting arms 24a. As shown in FIG. 3B, in a state that the top end portions of the supporting arms 24a are turned downward and the opening and closing clamp 24 is closed, because the tray 2 held between the supporting arms 24a is brought into restrict to moving downward by the engaging portions 24b at the top ends of the supporting arms 24a, the tray 2 can be separated from the tray holding unit 21, that is, the tray 2 is held by the tray holding unit 21. When the above-described state is changed to the state that the cylinder apparatuses are driven, the top end portions of the supporting arms 24a are turned in the direction of separating from each other, and the opening and closing clamp 24 is opened, the above-described restriction by the engaging portions 24b is released, and the tray 2 is brought into release.

The guide pin 26 is provided on the lower surface of the pusher base 22B downward, in standing. The guide pins 26 functions as an engaging portion of the present invention. When the opening and closing clamp 24 holds the tray 2, the guide pin 26 is fitted into a guide hole 2e of the tray 2, functioning as an engaged portion of the present invention. Thereby, the tray 2 held by the opening and closing clamp 24 is positioned against the tray holding unit 21.

The contact pusher 25 is installed with play at the base unit 22 in the state that lower end portions of the contact pusher 25 are projected downward. A plurality of contact pushers 25 are installed at the base unit 22, corresponding to following concave portions 2a of the tray 2, respectively. When the opening and closing clamp 24 holds the tray 2, because the lower end portions of each contact pusher 25 are fitted into each concave portion 2a, the contact pusher 25 brings the IC 1 provided at each concave portion 2a into pressure contact with the tray 2. Each contact pusher 25 comprises pressure contact portions 25a projecting downward, for pressure contacting leads 3 of the IC 1 with contactors 5 of the IC socket 4. At flange portions 25b at upper ends of each contact pusher 25, guide pins 27 are provided downward in standing, so as to vertically go through extension portions 22c of the pusher base 22B.

The IC socket 4 (test section) is arranged under the test stage 20, and electrically connected to an IC tester not shown in figures. At corner positions on an upper surface of the IC socket 4, guide pins 4a are provided upward in standing. Further, at center positions on the upper surface of the IC socket 4, a pair of contactors 5 is provided so as to project upward. In the state that the leads 3 of the IC 1 are contacted with the contactors 5 respectively, the IC tester tests the electric characteristic of the IC 1.

The tray 2 is formed in a rectangular shape, so as to be loaded onto a plurality of other trays 2. The tray 2 comprises a plurality of concave portions 2a which are formed in a rectangular shape and arranged lengthwise and crosswise, for horizontally receiving the ICs 1 respectively. On a bottom surface of each concave portion 2a, ribs 2f are projected in order to position the IC 1 received in the concave portion 2a, and connecting opening portions 2b are provided in order to bring the leads 3 of the IC 1 received in the concave portion 2a into go down the tray 2. Therefore, in the state that the IC 1 is provided at the tray 2, it is possible to test the electric characteristic of the IC 1.

Further, guide holes 2e and 2c through which guide pins 26 and 27 of the tray holding unit 21 go respectively are formed so as to go through the tray 2 vertically, and guide holes 2d through which guide pins 4a of the IC socket 4 go are formed so as to go through the tray 2 vertically.

Next, a behavior of the test stage 20 will be explained in detail.

First, the test stage 20 holds the tray 2 on the sending shuttle 12 waiting at the test preparative position P1. That is, after the XY stage moves the tray holding unit 21 to the position opposite to the tray 2 on the sending shuttle 12 horizontally, the elevator moves the tray holding unit 21 down. Then, the tray holding unit 21 fits the guide pins 26 and 27 into the guide holes 2e and 2c of the tray 2 respectively, and the lower end portions of each contact pusher 25 into each concave portion of the tray 2. Thereby, the tray 2 is positioned against the base unit 22 and each contact pusher 25, and each IC 1 contained in each concave portion 2a of the tray 2 is pressure contacted with the tray 2, by the contact pusher 25. In the above-described state, when the cylinder apparatus is driven, the opening and closing clamp 24 is brought into close. Therefore, as shown in FIG. 3B, the tray 2 on the sending shuttle 12 is held by the tray holding unit 21.

Then, the test stage 20 transfers the ICs 1 kept included in the tray 2 held by the tray holding unit 21 to the IC socket 4 in order. That is, when the XY stage moves the tray holding unit 21 horizontally, any one which will be called a first IC, of the ICs 1 included in the tray 2 is moved to the position opposite to the IC socket 4 horizontally. Thereafter, when the elevator moves the tray holding unit 21 down, the first IC is transferred to the IC socket 4. At the above-described time, because the guide pins 4a of the IC socket 4 are fitted into the guide holes 2d of the tray 2, the first IC is positioned against the IC socket 4. Further, because the leads 3 of the first IC are pushed between the contactors 5 of the IC socket 4 and the pressure contacting portions 25a of the contact pusher 25, the leads 3 of the first IC are contacted with the contactors 5 of the IC socket 4. In the above-described state, after the electric characteristic of the first IC is tested, when the elevator moves the tray holding unit 21 up, the tray 2 is separated from the IC socket 4. Then, when the XY stage moves the tray holding unit 21 horizontally, another one which will be called a second IC, of the ICs 1 included in the tray 2 is moved to the position opposite to the IC socket 4 horizontally. Thereafter, like the first IC, the second IC is transferred to the IC socket 4. Thereafter, the test stage 20 carries out the above-described processing continuously, and transfers the ICs 1 included in the tray 2 to the IC socket 4 in order.

As described above, when the test stage 20 finishes testing the electric characteristic of all the ICs 1 included in the tray 2, the test stage 20 transfers the tray 2 to on the receiving shuttle 13 waiting at the receiving preparative position P2. That is, after the XY stage moves the tray holding unit 21 to on the receiving shuttle 13 horizontally, the elevator moves the tray holding unit 21 down, and loads the tray 2 onto the receiving shuttle 13. Then, when the cylinder apparatus is driven, the opening and closing clamp 24 is brought into open. Thereby, because the engagement of the engaging portion 24b is released, the tray 2 is released on the receiving shuttle 13.

Therefore, when the tray 2 is transferred to on the receiving shuttle 13, the test stage 20 is moved to the test preparative position P1 in order to receive the next IC 1.

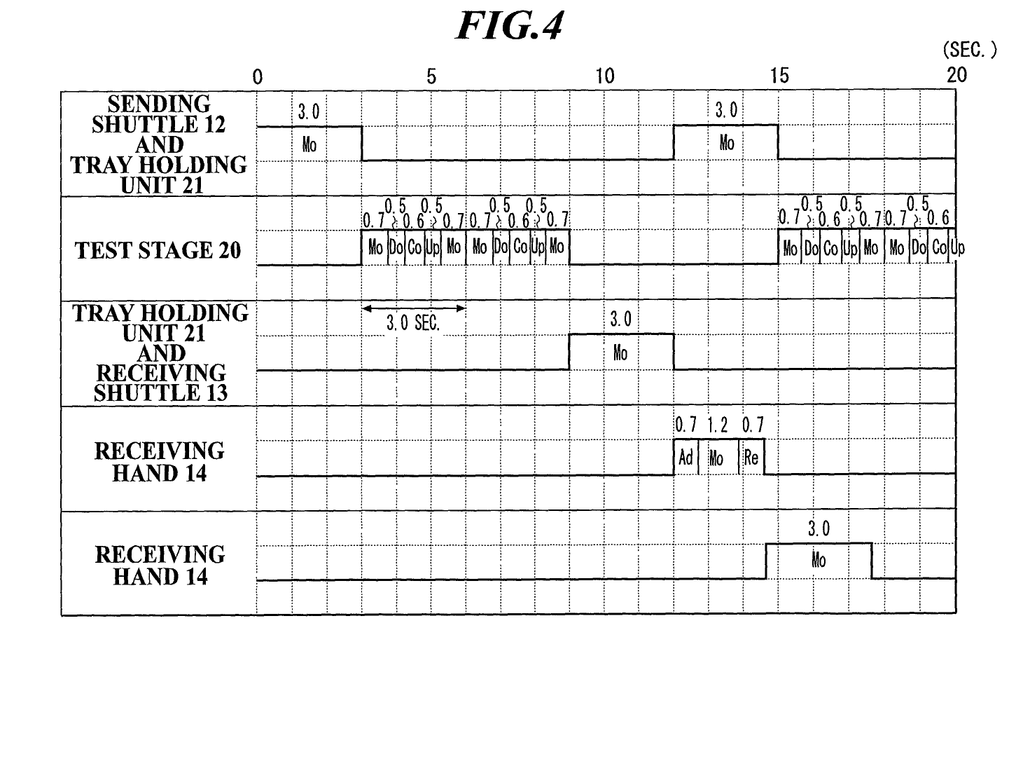

Next, each processing carried out by the above-described autohandler 100 will be explained with reference to FIG. 4.

First, the autohandler 100 carries out the processing of transferring the tray 2 from the loader 11 to the test stage 20. The processing (Mo) comprises a step wherein the sending shuttle 12 transfers the tray 2 of the loader 11 to the test preparative position P1, and a step wherein the tray holding unit 21 holds the tray 2 on the sending shuttle 12 waiting at the test preparative position P1. The auto handler 100 requires 3.0 seconds for carrying a cycle of the above-described steps (Mo). Because the tray 2 includes a plurality of ICs 1 which have not been tested yet, the processing time for every IC 1 requires less than 3.0 seconds. For example, in case the tray 2 includes ten ICs 1 therein, the processing time for every IC 1 is 0.3 second.

Next, the autohandler 100 carries out the processing of transferring the ICs 1 which have not been tested yet in the tray 2, to the IC socket 4. The processing comprises a step (Mo) wherein the XY stage moves the tray holding unit 21 horizontally, and arranges any one (first IC) of the ICs 1 included in the tray 2 at the position opposite to the IC socket 4, a step (Do) wherein the elevator moves the tray holding unit 21 down, and transfers the first IC to the IC socket 4, a step (Co) wherein the contact pusher 25 brings the first IC into contact with the IC socket 4 (a step wherein the IC tester tests the electric characteristic of the IC 1), a step (Up) wherein the elevator moves the tray holding unit 21 up, and separates the tray 2 from the IC socket 4, and a step (Mo) wherein the XY stage moves the tray holding unit 21 horizontally, and returns the tray 2 to the original position. The autohandler 100 requires 3.0 seconds for carrying out a cycle of the above-described steps (Mo, Do, Co, Up, Mo). That is, the autohandler 100 requires 3.0 seconds for testing the electric characteristic of one IC 1. The autohandler 100 continuously carries out the above-described processing, according to the number of the ICs 1 included in the tray 2. Herein, although the timing chart in case the tray 2 includes two ICs 1 has been shown as an example in FIG. 4, it is not limited to the embodiment.

Then, the autohandler 100 carries out the processing of transferring the tray 2 from the test stage 20 to the receiving buffer P3. The processing (Mo) comprises a step wherein the tray holding unit 21 hands the tray 2 to the receiving shuttle 13, and a step wherein the receiving shuttle 13 transfers the tray received from the tray holding unit 21 to the receiving buffer P3. The autohandler 100 requires 3.0 seconds for carrying out a cycle of the above-described steps (Mo). Because the tray 2 includes a plurality of ICs 1 which have not been tested yet therein, the processing time for every IC 1 is less than 3.0 seconds.

Thereafter, the autohandler 100 carries out the processing of transferring the tray 2 from the loader 11 to the test stage 20, the processing of transferring the ICs 1 which have not been tested yet in the tray 2 to the IC socket 4, and the processing of the transferring the tray 2 from the test stage 20 to the receiving buffer P3, in order.

Further, when the autohandler 100 finishes the processing of transferring the ICs 1 which have not been tested yet in the tray 2 to the IC socket 4, at the same time as the above-described processing of transferring the tray 2 from the loader 11 to the test stage 20, the autohandler 100 starts the processing of selecting the ICs 1 decided to be a defective device from the ICs 1 which have been tested in the tray 2 on the receiving shuttle 13 waiting at the receiving buffer P3, and transferring the selected ICs 1 to the sorting unit 16. The processing comprises a step (Ad) wherein the receiving hand 14 adsorbs the IC 1 on the receiving shuttle 13, a step (Mo) wherein the receiving hand 14 moves from on the receiving shuttle 13 to the sorting unit 16, and a step (Re) wherein the receiving hand 14 releases the adsorption of the IC 1 on the sorting unit 16. The autohandler 100 requires 2.6 seconds for carrying out a cycle of the above-described steps (Ad, Mo, Re). The above-described processing is continuously carried out until all the ICs 1 decided to be a defective device, are removed from the tray 2.

After the autohandler 100 finishes the processing of transferring the ICs 1 decided to be a defective device to the sorting unit 16, the autohandler 100 starts the processing of transferring the tray 2 including only the ICs 1 decided to be a non-defective device from the receiving shuttle 13 to the unloader 15. The processing (Mo) comprises a step wherein the receiving hand 14 adsorbs the tray 2 on the receiving shuttle 13, a step wherein the receiving hand 14 moves from on the receiving shuttle 13 to the unloader 15, and a step wherein the receiving hand 14 releases the adsorption of the tray 2 on the unloader 15. The autohandler 100 requires 3.0 seconds for carrying out a cycle of the above-described steps (Mo). Because the tray 2 includes a plurality of ICs 1 which have been tested therein, the processing time for every IC 1 is less than 3.0 seconds.

As described above, according to the autohandler 100 according to the present embodiment, because the autohandler 100 comprises a structure capable of transferring the ICs 1 which have not been tested and which are kept included in the tray 2, to the IC socket 4 in order, comparative with transferring the ICs 1 which have not been tested to the IC socket 4 one by one, it is possible to extremely shorten the transfer time for every IC 1.

Further, because the transfer time for every IC 1 by each of the sending shuttle 12, the receiving shuttle 13 and the receiving hand 14 becomes shorter than the test time for every IC 1 by the test stage 20, it is possible to shorten the total processing time for every IC by shortening the test time for every IC 1.

Further, because each of the sending shuttle 12, the test stage 20 and the receiving shuttle 13 transfers the ICs 1 which are kept included in the tray 2, it is possible to save an operation of exchanging the ICs 1. Consequently, it is possible to prevent an external defective, a static electricity breakdown and so on, of the device, from occurring.

Further, while the ICs 1 decided to be a defective device are removed from the tray 2 and transferred to the sorting unit 16, the ICs 1 decided to be a non-defective device are kept included in the tray 2 and transferred to the unloader 15. Consequently, it is possible to save an operation of exchanging the ICs 1 decided to be a non-defective device to the unloader 15.

Further, because the guide holes 2e and 2c are provided at the tray 2, and the guide pins 26 and 27 capable of engaging with and separating from the guide holes 2e and 2c are provided at the tray holding unit 21, it is possible to exactly position the tray 2 against the tray holding unit 21.

Further, because the contact pusher 25 brings each IC 1 included in the tray 2 into pressure contact with the tray 2, it is possible to prevent each IC 1 from falling from the tray 2, and to exactly bring the leads 3 of each IC 1 into contact with contactors 5 of the IC socket 4.

Further, because the contact pusher 25 is provided with play at the base unit 22, if there are uneven in positions at which the ICs 1 are provided more or less, the contact pusher 25 can absorb the unevenness. Consequently, it is possible that each contact pusher 25 stably brings each IC 1 into pressure contact with the tray 2.

Although the present invention has been explained according to the autohandler 100 of the above-described embodiment, it should also be understood that the present invention is not limited to the embodiment and various chanted and modifications may be made to the invention without departing from the gist thereof.

For example, although it has been explained that one IC socket 4 is provided as the test section according to the embodiment, a plurality of IC sockets 4 may be provided corresponding to the number of the ICs 1 included in the tray 2.

Further, it has been explained that the autohandler 100 comprises a structure of transferring the tray 2 from which the ICs 1 decided to be a defective device are removed and in which only the ICs 1 decided to be a non-defective device are remained, to the unloader 15. However, for example, the autohandler 100 may comprise a structure of supplying the ICs 1 decided to be a non-defective device to portions in the tray 2, from which the ICs 1 decided to be a defective device are removed and which become empty, filling the tray 2 with the ICs 1 decided to be a non-defective device, and transferring the tray 2 to the unloader 15.

In the above-described case, the autohandler 100 may comprise a non-defective device reserve unit for temporarily reserving the tray 2 including only the ICs 1 decided to be a non-defective device, near the receiving buffer P3. Further, the autohandler 100 may supply the ICs 1 in the tray 2 reserved in the non-defective device reserve unit, to another tray 2, in order to fill the another tray 2 with the ICs 1 decided to be a non-defective device. Further, the autohandler 100 may use the receiving hand 14 in order to transfer the tray 2 to the non-defective device reserve unit, and transfer the ICs 1 from the non-defective reserve unit to the receiving buffer P3. That is, the non-defective reserve unit and the receiving hand 14 may function as a supplying section of the present invention. According to the autohandler 100 comprising the above-described structure, it is possible to fill the tray 2 of the unloader 15 with the ICs 1 decided to be a non-defective device.

According to the present invention, some effects will be indicated, as follows.

As described above, comparative with transferring devices which have not been tested to the test section one by one, it is possible to extremely shorten the processing time for every device when transferring every device which has not been tested to the test section. Consequently, in case the test time for every device is short, because the transfer time for every device can be shortened, it is possible to shorten the total processing time for every device.

Further, because each of the sending shuttle, the test stage and the receiving shuttle transfers devices kept included in the tray, it is possible to save an operation of exchanging the devices. Consequently, it is possible to reduce occurrences of an external defective, a static electricity breakdown and so on, of the device.

Further, it is possible to transfer a plurality of devices at a time, and to test an electric characteristic of devices kept included in the tray.

Further, it is possible to transfer each device kept included in the tray, to the test section.

Further, it is possible to exactly position the tray against the tray holding section.

Further, it is possible to prevent each device from falling from the tray, and to exactly bring the lead of each device into contact with the contact portion such as a contactor or the like, provided at the test section.

Further, if there are uneven in positions at which devices are provided more or less, the contact pusher can absorb the unevenness. Consequently, it is possible that each contact pusher stably brings each device into pressure contact with the tray.

Further, it is possible to save an operation of exchanging devices decided to be a non-defective device to the unloader.

Further, it is possible to fill the tray of the unloader with devices to be a non-defective device.

The entire disclosure of Japanese Patent Application No. Tokugan 2000-392773 filed on Dec. 25, 2000 including specification, claims, drawings and summary are incorporated herein by reference in its entirety.

What is claimed is:

1. An autohandler for transferring devices which have not been tested to a test section, and sorting devices which have been tested on the basis of results of a test carried out by the test section, the autohandler comprising:
a loader in which a tray including a plurality of devices which have not been tested is loaded;
a sending shuttle for transferring the tray loaded in the loader to a test preparative position;
a test stage for holding the tray on the sending shuttle waiting at the test preparative position, transferring the devices which have not been tested and which are kept included in the tray held, to the test section in order, and transferring the tray to a receiving preparative position when the test section carries out the test to all the devices included in the tray;
a receiving shuttle for receiving the tray from the test stage at the receiving preparative position, and transferring the tray received to a receiving buffer; and
a sorting section for sorting the devices which have been tested in the tray on the receiving shuttle waiting in the receiving buffer, on the basis of results of the test carried out by the test section.

2. The autohandler as claimed in claim 1, wherein the tray comprises a plurality of concave portions formed therein, at which the devices are provided respectively, and a plurality of connecting opening portions formed on bottom surfaces of the concave portions respectively, through which leads of the devices provided at the concave portions go down the tray.

3. The autohandler as claimed in claim 1, wherein the test stage comprises:
a tray holding section for holding the tray;
a XY stage for moving the tray holding section horizontally, to arrange the devices included in the tray opposite the test section in order; and
an elevator for moving the tray holding section vertically, to separate the devices included in the tray and arranged opposite the test section, from the test section.

4. The autohandler as claimed in claim 3,
wherein the tray comprises an engaged portion provided thereat,
the tray holding section comprises an engaging portion provided thereat, the engaging portion capable of engaging with and separating from the engaged portion, and
the tray is positioned against the tray holding section, in a state wherein the engaging portion engages with the engaged portion.

5. The autohandler as claimed in claim 4,
wherein the tray holding section comprises a base portion provided thereat, having the engaging portion, and a contact pusher provided at the base portion, for bringing each device included in the tray into pressure contact with the tray.

6. The autohandler as claimed in claim 5,
wherein the contact pusher is prepared for every device included in the tray, and provided with play at the base portion.

7. The autohandler as claimed in claim 1, wherein the sorting section comprises:
an unloader for receiving devices which have been tested to be decided to be a non-defective device;
a sorting unit for receiving devices which have been tested to be decided to be a defective device;
a defective device transferring section for selecting only devices decided to be a defective device from devices which have been tested in the tray on the receiving shuttle waiting in the receiving buffer, and transferring the devices selected to the sorting unit; and
a non-defective device transferring section for transferring the tray from which devices decided to be a defective device are removed and which includes only devices decided to be a non-defective device, from the receiving shuttle to the unloader.

8. The autohandler as claimed in claim 7, further comprising a supplying section for supplying devices decided to be a non-defective device to portions in the tray, from which devices decided to be a defective device are removed and transferred to the sorting unit by the defective device transferring section and which become empty, to fill the tray with devices decided to be a non-defective device.

9. A testing method for handling and testing devices, comprising the steps of:
loading a tray including a plurality of devices which have not been tested in a loader;
transferring the tray loaded in the loader to a test preparative position;
holding the tray waiting at the test preparative position;
transferring the devices which have not been tested and which are kept included in the tray held, to a test section in order;
testing the devices which are kept included in the tray by the test section;
transferring the tray to a receiving preparative position when the test section tests all the devices included in the tray;
receiving the tray at the receiving preparative position;
transferring the tray received to a receiving buffer; and
sorting the devices which have been tested in the tray waiting in the receiving buffer, on the basis of results tested by the test section.
